(19) United States
(12) Patent Application Publication
(10) Pub. No.: US 2004/0003940 A1
(43) Pub. Date: Jan. 8, 2004

(54) Circuit board for flip-chip semiconductor package and fabrication method thereof

(76) Inventors: Jin-Chuan Bai, Hsinchu (TW); Chung-Che Tsai, Hsinchu (TW)

Correspondence Address: ANDERSON KILL & OLICK, P.C., 1251 Avenue of the Americas, New York, NY, 10020-1182, US

(21) Appl. No.: 10/313,675

(22) Filed: Dec. 5, 2002

(30) Foreign Application Priority Data
Jul. 3, 2002 (TW) 91114734

(51) Int. Cl. H05K 1/03; H05K 3/28

(52) U.S. Cl. 174/258; 29/846; 428/209

(57) ABSTRACT

A circuit board for a flip-chip semiconductor package and a fabrication method of the circuit board are provided. A core layer is coated with a resin material on a surface thereof where a plurality of bond pads are formed. Laser-etching technology is adopted to form a plurality of openings through the resin material corresponding in position to the bond pads, whereby the bond pads are exposed via the openings to be bonded with solder balls or bumps, so as to allow the circuit board to be electrically connected to an external device or a chip via the solder balls or bumps. This circuit board is beneficial to allow precise exposure of the bond pads in position, which can improve quality and yield of the circuit board and make the circuit board suitably applied to high-level products with fine-pitch arrangement of conductive elements for electrical connection purposes.

### FIELD OF THE INVENTION

The present invention relates to circuit boards, and more particularly, to a circuit board for use in a flip-chip semiconductor package and a method for fabricating the circuit board.

### BACKGROUND OF THE INVENTION

In conventional processes for fabricating a circuit board such as substrate or printed circuit board (PCB), the first step is to attach at least a copper film to a core layer and pattern the copper film to form a plurality of conductive traces on the core layer. Then, solder mask is applied over the conductive traces, wherein solder mask is first spread over the core layer by a printing or spraying process, and then subject to exposing, developing and etching processes to selectively remove undesirable part of solder mask; remaining solder mask is baked under a high temperature and cured to form protective coating that protects the conductive traces on the core layer against oxidation or short circuit without affecting electrical performances thereof.

However, the above fabricated circuit board renders significant drawbacks. For example, due to material properties of solder mask, multiple times of printing or spraying processes are usually required to apply and accumulate solder mask to a predetermined thickness. This thereby increases process complexity, costs and time consumption in fabrication of the circuit board.

Moreover, during multiple application of solder mask over the core layer, air may easily enter into solder mask to form voids; the presence of voids may lead to popcorn effect to the circuit board under a high temperature condition in subsequent fabrication processes, thereby damaging reliability of the fabricated circuit board.

Thickness and surface planarity of multiply-accumulated solder mask are hardly controlled and thereby affect performance quality of subsequent fabrication processes. For example, when an encapsulant is formed by a resin compound to encapsulate a chip mounted on the circuit board with uneven solder mask, resin flash may easily occur at peripheral portions or edges of the encapsulant on the circuit board, making a fabricated product have a defective appearance. As a result, a deflash process is usually performed to remove resin flash, which would undesirably increase process complexity and fabrication costs.

Besides, due to mismatch in coefficient of thermal expansion (CTE) between solder mask and the copper-made conductive traces and core layer of the circuit board, thermal stress would be produced under a high temperature condition to easily cause warpage or delamination of the circuit board, thereby adversely affecting quality and yield of fabricated products.

Furthermore, during the etching process for selectively removing solder mask to expose predetermined part of the conductive traces (such as trace terminals acting as bond pads or bond fingers) on the core layer, as solder mask is baked at a high temperature and slightly shrinks, the trace terminals intended to be exposed are hardly positioned precisely for actual exposure, which may lead to significant inaccuracy between actual exposed terminal positions and predetermined exposed positions, and thus undesirably influences quality of electrical connection for the circuit board.

In order to solve the above problem of positioning inaccuracy, laser-etching technology may be employed to remove solder mask and precisely expose intended trace terminals. However, as shown in FIG. 2, when a surface 120 of a solder mask layer 12 is not with satisfactory planarity or uniform thickness, openings 13 formed through the solder mask layer 12 by laser-etching technology lead to different exposure of bond pads 11 disposed on a core layer 11. For example, a bond pad 11a covered by a relatively thinner portion of the solder mask layer 12 would be completely exposed to a corresponding one of the openings 13 formed by laser-etching the solder mask layer 12. After applying a solder ball and solder paste (not shown) onto this exposed bond pad 11a, during a solder-reflow process, the solder ball and solder paste may be wetted to side surfaces of the bond pad 11a, which may result in problems such as short circuit and poor electrical connection.

In addition, the laser-etching process is relatively cost-ineffective to implement, and usually not suitable for a circuit board with relatively large-area trace terminals (bond pads or bond fingers). This is because trace terminals having large surface area need multiple performances of the laser-etching process for terminal exposure, thereby leading to significant increase in fabrication costs of the circuit board. Therefore, in consideration of cost concern, laser-etching technology is rather limited in practical application.

Therefore, the problem to be solved herein is to provide a circuit board formed by effectively utilizing laser-etching technology to eliminate conventional drawbacks rendered through the use of solder mask.

### SUMMARY OF THE INVENTION

An objective of the present invention is to provide a circuit board for a flip-chip semiconductor package, which allows bond pads formed on the circuit board to be precisely exposed in position by laser-etching technology and subsequently bonded with solder bumps or balls, thereby improving quality and yield of fabricated products.

Another objective of the invention is to provide a circuit board for a flip-chip semiconductor package, which can be suitably applied to high-level electronic products with high-density and fine-pitch arrangement of conductive elements for electrical connection purposes.

A further objective of the invention is to provide a circuit board for a flip-chip semiconductor package, which can effectively reduce process complexity and costs in fabrication of the circuit board.

In accordance with the above and other objectives, the present invention proposes a circuit board for a flip-chip semiconductor package, comprising: a core layer formed with a plurality of bond pads on at least a surface thereof, the core layer being made of a first resin material; and a cover layer applied over the surface of the core layer where the bond pads are disposed, the cover layer being formed with a plurality of laser-etching-fabricated openings penetrating through the cover layer, wherein the openings correspond in position to the bond pads, allowing the bond pads to be exposed via the openings, and the cover layer is made of a second resin material. The exposed bond pads are subsequently bonded with solder balls or bumps to electrically connect the circuit board to an external device or a chip.

The second resin material for making the cover layer may be composed of (but not limited to) a single resin material such as epoxy resin, polyimide resin, BT (bismaleimide triazine) resin, FR4 resin or FR5 resin, or a mixture of at least two foregoing resin materials. Moreover, the second resin material has coefficient of thermal expansion (CTE) similar or identical to that of the first resin material for fabricating the core layer; this can effectively reduce thermal stress produced in the circuit board under a high temperature condition, and thereby prevents warpage and delamination of the circuit board.

The cover layer of the above circuit board may be completely coated over the core layer by single-time application and formed with satisfactory surface planarity, which thereby reduces process complexity and costs in fabrication as well as assuring yield of the fabricated circuit board.

A characteristic feature of the above circuit board is the use of laser-etching technology to form a plurality of openings penetrating through the cover layer, whereby bond pads disposed on the circuit board can be exposed via the openings. Laser-etching technology would precisely determine opening positions of the cover layer corresponding to the bond pads on the circuit board to significantly reduce positional inaccuracy between the openings and the bond pads, thereby allowing precise exposure of the bond pads to be bonded with solder balls or bumps. Therefore, the circuit board according to the invention can improve yield of fabricated products, and is suitably applied to high-level electronic products with high-density and fine-pitch arrangement of conductive elements for electrical connection purposes.

### BRIEF DESCRIPTION OF THE DRAWINGS

The present invention can be more fully understood by reading the following detailed description of the preferred embodiments, with reference made to the accompanying drawings, wherein:

FIGS. 1A to 1C are cross-sectional schematic diagrams showing process steps for fabricating a circuit board according to the invention; and

FIG. 2 (PRIOR ART) is a cross-sectional view of a conventional circuit board.

### DETAILED DESCRIPTION OF THE PREFERRED EMBODIMENTS

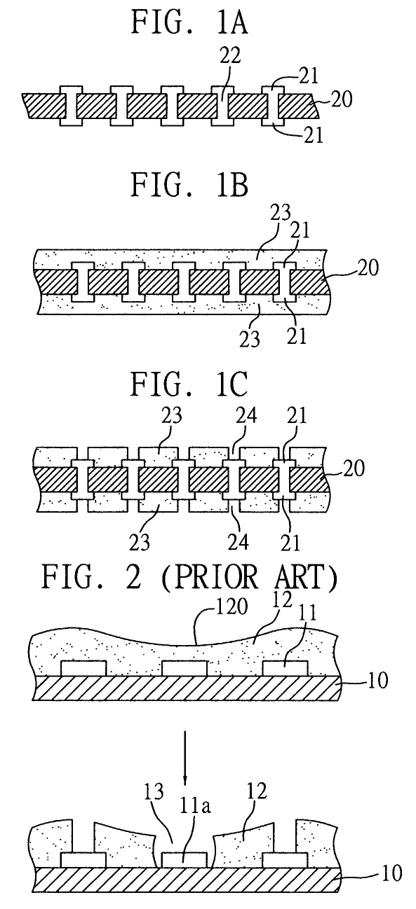

Preferred embodiments for a circuit board for a flip-chip semiconductor package proposed in the present invention are described in more detail as follows-with reference to FIGS. 1A to 1C.

As shown in FIG. 1C, the circuit board according to the invention is composed of a core layer 20 that is formed on its upper and lower surfaces with a plurality of bond pads 21, and a plurality of conductive vias 22 are formed through the core layer 20 for electrically interconnecting the bond pads 21 on the upper and lower surfaces of the core layer 20. A cover layer 23 made of a resin material is applied respectively over the upper and lower surfaces of the core layer 20; the cover layer 23 is formed with a plurality of openings 24 by laser-etching technology corresponding in position to the bond pads 21, allowing the bond pads 21 to be exposed via the openings 24. The exposed bond pads 21 may be bonded with solder balls or bumps to electrically connect the circuit board to an external device or a chip.

The cover layer 23 may be made of a resin material having coefficient of thermal expansion (CTE) similar or identical to that of the core layer 20; this helps effectively reduce thermal stress produced in the circuit board under a high temperature condition, and thus prevents warpage or delamination of the circuit board from occurrence.

FIGS. 1A to 1C illustrate process steps for fabricating the above circuit board according to the invention.

Referring to FIG. 1A, the first step is to prepare a core layer 20, which may be made of a conventional resin material such as epoxy resin, polyimide resin, BT (bismaleimide triazine) resin, FR4 resin, etc. Moreover, the core layer 20 is formed on its upper and lower surfaces with a plurality of bond pads 21, and a plurality of conductive vias 22 are formed through the core layer 20 for electrically interconnecting the bond pads 21 on the upper and lower surfaces of the core layer 20.

The bond pads 21 are fabricated by first attaching at least a copper film respectively on the upper and lower surfaces of the core layer 20; then, the copper films are patterned to form the bond pads 21 at predetermined positions, and a conventional plating process is performed to plate a conductive metal such as copper in a plurality of vias penetrating through the core layer 20 to form the conductive vias 22 that electrically interconnect the bond pads 21 on the upper and lower surfaces of the core layer 20. Since the patterning and plating processes are conventional technology, no further description thereto is to be repeated herein.

Then, referring to FIG. 1B, a conventional printing, molding or pressing process is performed to apply a cover layer 23 made of a resin material respectively over the upper and lower surfaces of the core layer 20 in a manner as to hermetically cover the bond pads 21 formed on the core layer 20.

The above cover layer 23 can be completely coated over the core layer 20 by single-time application and formed with satisfactory surface planarity. As compared to the use of conventional solder mask that requires multiple times of application to achieve a desirable thickness of solder mask and easily leads to surface unevenness, therefore, the circuit board according to the invention can effectively reduce process complexity and fabrication costs as well as assure yield of fabricated products.

The cover layer 23 may be composed of (but not limited to) a single resin material such as epoxy resin, polyimide resin, BT (bismaleimide triazine) resin, FR4 resin or FR5 resin, or a mixture of at least two foregoing resin materials. Moreover, the cover layer 23 is made of a resin material having coefficient of thermal expansion (CTE) similar or identical to that of the core layer 20; this can significantly reduce thermal stress produced in the circuit board under a high temperature condition, and thus prevents warpage and delamination of the circuit board.

Finally, referring to FIG. 1C, a plurality of openings 24 are formed through the cover layer 23 by laser-etching technology; the openings 24 correspond in position to the bond pads 21 formed on the core layer 20, such that the bond pads 21 can be exposed via the openings 24 and bonded with solder balls or bumps to electrically connect the circuit board to an external device or a chip. This thereby completes fabrication of the circuit board according to the invention.

A characteristic feature of the above circuit board is the use of laser-etching technology to form a plurality of openings 24 penetrating through the cover layer 23, to thereby expose the bond pads 21 disposed on the circuit board via the openings 24. The laser-etching process is advanced technology that can precisely determine positions of the openings 24 formed through the cover layer 23 to correspond to the bond pads 21 on the circuit board, and with satisfactory surface planarity of the cover layer 23, positional inaccuracy between the openings 24 and the bond pads 21 can be significantly reduced; further, the laser-etching technology would not damage copper-made bond pads 21, thereby improving quality and yield of the fabricated circuit board. The foregoing benefit is critical for a circuit board used in a flip-chip package structure; as bond pads 21 formed on a flip-chip circuit board are normally arranged in high density, slightly positional inaccuracy would lead to significant deviation in position between openings 24 formed through the cover layer 23 and the bond pads 21 intended to be exposed; this adversely affects performance quality of subsequent fabrication processes. For example, when solder bumps or balls are implanted at bond pads formed on the circuit board, with inaccurate exposure of the bond pads, the solder bumps or balls may not be completely bonded to the bond pads to thereby degrading quality of electrical connection.

Moreover, an exposed portion of each bond pad 21 arranged on the flip-chip circuit board is normally dimensioned as 100 mm (i.e. opening 24); such a small opening 24 is suitably formed by laser-etching technology with high positioning precision. And, the laser-etching technology allows single process performance to accomplish the opening 24, thereby reducing time consumption in fabrication of the circuit board.

Further due to high positioning precision of the laser-etching technology and good surface planarity of the circuit board (or the cover layer 23) according to the invention, this circuit board is suitably applied to high-level electronic products with high-density and fine-pitch arrangement of conductive elements for electrical connection purposes; the above benefits rendered by the circuit board according to the invention can not be accomplished through the use of a conventional circuit board applied with solder mask.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A circuit board for a flip-chip semiconductor package, comprising:
a core layer formed with a plurality of bond pads on at least a surface thereof, the core layer being made of a first resin material; and
a cover layer applied over the surface of the core layer where the bond pads are disposed, the cover layer being formed with a plurality of laser-etching-fabricated openings penetrating through the cover layer, wherein the openings correspond in position to the bond pads, allowing the bond pads to be exposed via the openings, and the cover layer is made of a second resin material.

2. The circuit board of claim 1, wherein the second resin material is selected from the group consisting of epoxy resin, polyimide resin, BT (bismaleimide triazine) resin, FR4 resin and FR5 resin.

3. The circuit board of claim 1, wherein the second resin material is identical to the first resin material.

4. The circuit board of claim 1, wherein coefficient of thermal expansion of the second resin material is similar to that of the first resin material.

5. The circuit board of claim 1, wherein coefficient of thermal expansion of the second resin material is identical to that of the first resin material.

6. The circuit board of claim 1, wherein if the core layer is provided with a plurality of bond pads on opposing surfaces thereof, a plurality of conductive vias are formed through the core layer to electrically interconnect the bond pads on the opposing surfaces of the core layer.

7. A fabrication method of a circuit board for a flip-chip semiconductor package, comprising the steps of:
preparing a core layer formed with a plurality of bond pads on at least a surface thereof, the core layer being made of a first resin material; and
applying a cover layer over the surface of the core layer where the bond pads are disposed, and etching the cover layer by laser to form a plurality of openings penetrating through the cover layer, wherein the openings correspond in position to the bond pads, allowing the bond pads to be exposed via the openings, and the cover layer is made of a second resin material.

8. The fabrication method of claim 7, wherein the second resin material is selected from the group consisting of epoxy resin, polyimide resin, BT (bismaleimide triazine) resin, FR4 resin and FR5 resin.

9. The fabrication method of claim 7, wherein the second resin material is identical to the first resin material.

10. The fabrication method of claim 7, wherein coefficient of thermal expansion of the second resin material is similar to that of the first resin material.

11. The fabrication method of claim 7, wherein coefficient of thermal expansion of the second resin material is identical to that of the first resin material.

12. The fabrication method of claim 7, wherein the cover layer is applied over the core layer by a printing process.

13. The fabrication method of claim 7, wherein the cover layer is applied over the core layer by a molding process.

14. The fabrication method of claim 7, wherein the cover layer is applied over the core layer by a pressing process.

15. The fabrication method of claim 7, wherein if the core layer is provided with a plurality of bond pads on opposing surfaces thereof, a plurality of conductive vias are formed through the core layer to electrically interconnect the bond pads on the opposing surfaces of the core layer.
